(19) United States
(12) Patent Application Publication
(10) Pub. No.: US 2021/0341692 A1
(43) Pub. Date: Nov. 4, 2021

(54) HEAT DISSIPATION ASSEMBLY AND COMMUNICATION MODULE

(71) Applicant: CHENGDU SUPERXON COMMUNICATION TECHNOLOGY CO., LTD., Chengdu, Sichuan (CN)

(72) Inventors: Lang LIU, Chengdu (CN); Qing BAI, Chengdu (CN); Jiang DENG, Chengdu (CN)

(73) Assignee: CHENGDU SUPERXON COMMUNICATION TECHNOLOGY CO., LTD., Chengdu, Sichuan (CN)

(21) Appl. No.: 17/283,407

(22) PCT Filed: Oct. 8, 2019
(86) PCT No.: PCT/CN2019/110008

§ 371 Date: Apr. 7, 2021

(30) Foreign Application Priority Data
Oct. 12, 2018 (CN) 201811190225.2

(51) Int. Cl. G02B 6/42; H05K 7/20

(52) U.S. Cl. CPC G02B 6/4271; H05K 7/20436

(57) ABSTRACT

A heat dissipation assembly and a communication module. The heat dissipation assembly includes a housing and a heat generation device disposed inside the housing, wherein the housing is provided therein with a heat insulation cavity around the periphery of the heat generation device, the heat insulation cavity is provided with a through hole, and the housing is provided therein with a heat conduction assembly disposed through the through hole and configured to conduct the heat of the heat generation device to the housing.

### CROSS-REFERENCE TO RELATED APPLICATIONS

The present disclosure claims the priority of the Chinese patent application No. 201811190225.2, filed with the Chinese Patent Office on Oct. 12, 2018 and entitled “Heat Dissipation Assembly and Communication Module”, which is incorporated herein by reference in its entirety.

### TECHNICAL FIELD

The present disclosure relates to the technical field of heat dissipation of electronic devices, and particularly to a heat dissipation assembly and a communication module.

### BACKGROUND ART

Electronic devices usually generate a lot of heat during operation. However, electronic devices have relatively high requirements on the operation temperature. An excessively high temperature will cause an electronic device to operate abnormally, and shorten the service life thereof, especially for a communication optical module which is even more demanding for constant operation temperature. When the operation temperature increases, the emission intensity of the optical module decreases with the increase of the temperature, and the wavelength of the signal emitted by the optical module shifts. Once a wavelength shift occurs, the optical packet signals will be partially lost when passing through an AWG (Arrayed Waveguide Grating)/Demux (demultiplexer), thus resulting in a packet loss during communication between an ONU (Optical Network Unit) and an OLT (Optical Line Terminal), which seriously affects the reliability of communication. Therefore, it is necessary to adopt a good heat dissipation structure to ensure constant temperature for the optical module, avoid the fluctuation of operation temperature, and ensure stable and reliable operation of the optical module.

At present, it is the general practice to dispose a heat conduction assembly directly between the optical module and the housing thereof, to transfer the heat generated by the optical device to the housing through the heat conduction assembly, so as to dissipate the heat to the outside through the housing, thereby achieving the object of dissipating heat from the optical module. However, this heat dissipation method may easily incur the problem of back transfer of heat, which causes frequent fluctuations of the temperature of the optical module and affects the operation performance of the optical module.

### SUMMARY

The present disclosure provides a heat dissipation assembly, comprising a housing and a heat generation device disposed inside the housing, wherein the housing is provided therein with a heat insulation cavity around the periphery of the heat generation device, the heat insulation cavity is provided with a through hole, and the housing is provided therein with a heat conduction assembly passing through the through hole and configured to conduct the heat of the heat generation device to the housing. The heat dissipation assembly of the present disclosure prevents, by the heat insulation cavity, the heat released from the high-temperature housing from being transferred back to the heat generation device in the housing, while conducting, by the heat conduction assembly, the heat of the heat generation device to the housing for heat dissipation, thus ensuring a good and stable heat dissipation effect, so that the heat generation device can operate at a relatively low constant temperature, which ensures the stable operation of the heat generation device, thus ensuring stable operation performance, and also effectively prolonging the service life of the device.

The present disclosure further provides a communication module using the above-described heat dissipation assembly, comprising an optical device and a circuit board, the optical device serving as the heat generation device in the above-described heat dissipation assembly, the circuit board being located inside the housing and at the outer side of the heat insulation cavity, the optical device being connected to the circuit board by an electrical connector passing through the heat insulation cavity, and the optical device being configured to transmit and receive optical signals.

### BRIEF DESCRIPTION OF DRAWINGS

FIG. 1 is a schematic structural diagram of a heat dissipation assembly provided by an embodiment of the present disclosure;

FIG. 2 is a schematic structural diagram of another heat dissipation assembly provided by an embodiment of the present disclosure;

FIG. 3 is a schematic structural diagram of still another heat dissipation assembly provided by an embodiment of the present disclosure;

FIG. 4 is a schematic structural diagram of still another heat dissipation assembly provided by an embodiment of the present disclosure;

FIG. 5 is a schematic structural diagram of still another heat dissipation assembly provided by an embodiment of the present disclosure;

FIG. 6 is a schematic structural diagram of still another heat dissipation assembly provided by an embodiment of the present disclosure;

FIG. 7 is a schematic structural diagram of still another heat dissipation assembly provided by an embodiment of the present disclosure;

FIG. 8 is a schematic exploded structural diagram of a communication module using the heat dissipation assembly provided by an embodiment of the present disclosure;

FIG. 9 is a schematic sectional structural diagram of the communication module provided by an embodiment of the present disclosure;

FIG. 10 is a schematic diagram of heat flow of the communication module provided by an embodiment of the present disclosure; and

FIG. 11 is a schematic structural diagram of a heat insulation cavity of the communication module provided by an embodiment of the present disclosure.

### DETAILED DESCRIPTION OF EMBODIMENTS

The technical solutions of the embodiments of the present disclosure will be clearly and completely described below with reference to the drawings of the embodiments of the present disclosure. Obviously, the embodiments described are only some of the embodiments of the present disclosure, rather than all of the embodiments of the present disclosure. All the other embodiments that are obtained by a person of ordinary skills in the art on the basis of the embodiments of the present disclosure without inventive effort shall be covered by the protection scope of the present disclosure.

It has been found by study that when heat generated by the heat generation device reaches the housing by means of the heat conduction assembly, the housing absorbs the heat and the temperature thereof rises, and then heat will be dissipated therefrom. Since the housing dissipates heat non-directionally, the heat will be transferred back to the heat generation device by radiation or contact, resulting in poor heat dissipation effect, and making it difficult to maintain the heat generation device at a relatively low constant temperature or to maintain a stable operation state of the heat generation device, thereby affecting the operation performance of the heat generation device.

In order to at least partially solve the above-described problem, an embodiment of the present disclosure provides a heat dissipation assembly capable of achieving directional heat dissipation, ensuring effective heat dissipation to the outside, and preventing heat from being transferred back, thereby ensuring that the device operates at a constant temperature, and ensuring that the device is in a stable operation state.

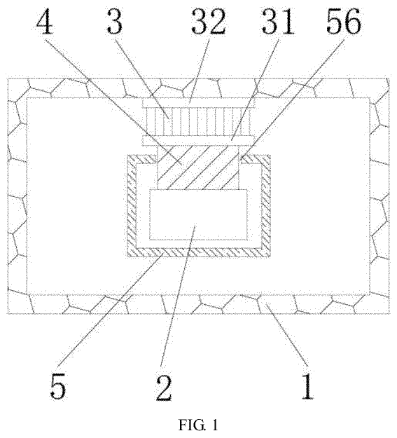

FIG. 1 shows a heat dissipation assembly provided by the present embodiment. The heat dissipation assembly mainly comprises a housing 1 and a heat generation device 2 disposed inside the housing 1. A heat conduction assembly is disposed between the heat generation device 2 and the housing 1. The heat conduction assembly is configured to conduct heat generated by the heat generation device 2 to the housing 1, and then dissipate the heat generated by the heat generation device 2 to the outside by using the large-area housing 1, so as to realize heat dissipation and cooling of the heat generation device 2, so that the heat generation device 2 can operate at a relatively low constant temperature, thus ensuring that the heat generation device 2 can always operate stably, and that the heat generation device 2 has good operation performance.

In the prior art, the heat conducted to the housing 1 raises the temperature of the housing 1, and at this time, the housing 1 radiates heat toward the outside and the heat generation device 2 so as to dissipate heat. That is, there exists the situation in which heat is transferred back to the heat generation device 2, and as a result, the heat dissipation effect is reduced, and the temperature of the heat generation device 2 fluctuates, which affects the operation stability of the heat generation device 2.

In order to avoid the above-mentioned situation, in this embodiment, a heat insulation cavity 5 is provided in the housing 1, the heat insulation cavity 5 is around the periphery of the heat generation device 2, and the heat insulation cavity 5 is provided with a through hole 56, one end of the heat conduction assembly is in thermal conduction, through the through hole 56, with the heat generation device 2, the other end of the heat conduction assembly is in thermal conduction with the housing 1, and the heat conduction assembly conducts the heat of the heat generation device 2 to the housing 1 for heat dissipation.

In order to ensure efficient heat dissipation performance so that the heat generation device 2 operates at a relatively low constant temperature, the heat conduction assembly mainly comprises a thermoelectric cooler (TEC), the cold end 31 of the thermoelectric cooler 3 is in thermal conduction with the heat generation device 2, and the hot end 32 of the thermoelectric cooler 3 is in thermal conduction with the housing 1. TEC is a device that produces cold energy using the thermoelectric effect of semiconductors. When the TEC is powered on, electron-hole pairs will be generated in the vicinity of the upper contact, resulting in that the internal energy is reduced and the temperature is decreased, and thus the upper contact absorbs heat from the outside and is referred to as the cold end 31; and as to the other end opposite to the upper contact, due to recombination of electron-hole pairs, the internal energy is increased, the temperature is increased, and this end dissipates heat to the ambient and is referred to as the hot end 32. The thermoelectric cooler 3 has the characteristics of no noise, no vibration, requiring no refrigerant, small size, light weight, etc., and is reliable in operation, simple to operate, and easy in cooling capacity adjustment, and is suitable for occasions with small space.

In order to reduce thermal resistance to improve the heat conduction efficiency, the heat conduction assembly may further comprise a heat conductor 4 disposed between the thermoelectric cooler 3 and the heat generation device 2, one side of the heat conductor 4 is attached to the heat generation device 2, and the other side of the heat conductor 4 is attached to cold end 31 of the thermoelectric cooler 3. In this way, the efficiency of heat transfer between the heat generation device 2 and the thermoelectric cooler 3 can be improved.

Optionally, the side of the heat conductor 4 attached to the heat generation device 2 assumes a structural surface having the same shape as the surface of the heat generation device 2, which can effectively increase the contact area, so that the heat conductor 4 can sufficiently transfer the heat generated by the heat generation device 2 to the cold end 31 of the thermoelectric cooler 3, thereby improving the heat dissipation efficiency, ensuring stable operation temperature of the heat generation device 2, and ensuring stable operation performance of the heat generation device 2.

Further, a heat conduction filler layer made of a heat conduction interface material is filled between the contact surfaces of the heat conductor 4 and the heat generation device 2, between the contact surfaces of the heat conductor 4 and the thermoelectric cooler 3 and between the contact surfaces of the thermoelectric cooler 3 and the housing 1, to increase the contact area of each contact surface, reduce the thermal resistance, and improve the heat conduction efficiency, thereby improving the heat dissipation effect.

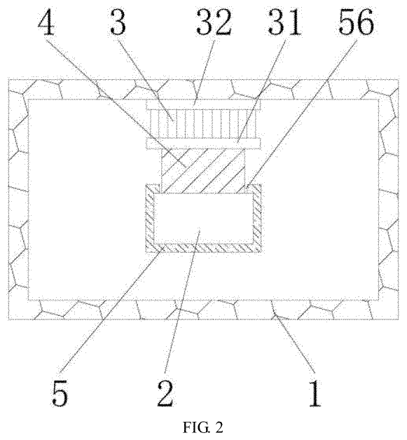

FIG. 2 is a schematic structural diagram of another heat dissipation assembly provided by the present embodiment. This heat dissipation assembly differs from the heat dissipation assembly shown in FIG. 1 in that the inner wall of the heat insulation cavity 5 is attached to the surface of the heat generation device 2, so that the heat insulation cavity 5 and the heat generation device 2 are more compact basically with no gap therebetween, thereby preventing the heat generated by the heat generation device 2 from being dissipated into and accumulating in the space between the heat insulation cavity 5 and the heat generation device 2. In this way, it is possible to ensure that the heat generated by the heat generation device 2 can be more efficiently conducted, through the through hole 56 of the heat insulation cavity 5, to the outside by means of the heat conduction assembly, thereby improving the heat dissipation effect.

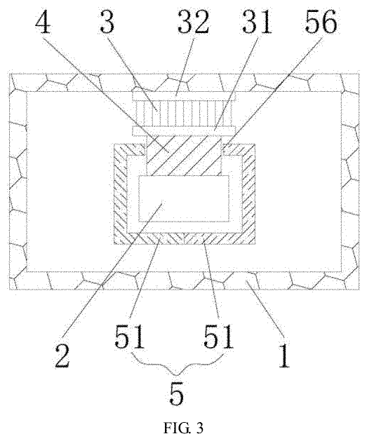

FIG. 3 is a schematic structural diagram of yet another heat dissipation assembly provided by the present embodiment, which differs from the heat dissipation assembly described above in that the heat insulation cavity 5 is constituted by detachably combining a plurality of sub-cavities 51, so that the heat insulation cavity 5 is more convenient to assemble and disassemble, and the structure of the sub-cavity 51 is simpler, which is easy to manufacture and low in cost.

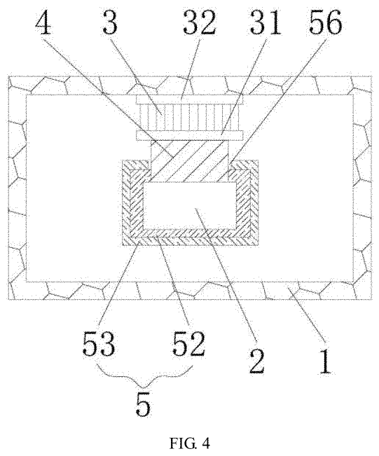

FIG. 4 is a schematic structural diagram of still another heat dissipation assembly provided by the present embodiment, which differs from the heat dissipation assembly described above in that the heat insulation cavity 5 is provided in a double-layered structure, wherein the inner layer is a heat conduction cavity layer 52 attached to the surface of the heat generation device 2, and the outer layer is a heat insulation cavity layer 53. The heat conduction cavity layer 52 is in thermal conduction with the heat conduction assembly, so that the heat absorbed by the heat conduction cavity layer 52 due to being attached to the heat generation device 2 is conducted to the housing 1 through the heat conduction assembly. Optionally, the heat conduction cavity layer 52 may be in thermal conduction with the heat conductor 4 or the cold end 31 of the thermoelectric cooler 3, and the heat conduction cavity layer 52 is in sufficient contact with the entire peripheral surface of the heat generation device 2, thereby effectively increasing the heat exchange area, improving the heat conduction efficiency and improving the dissipation effect on heat from the heat generation device 2.

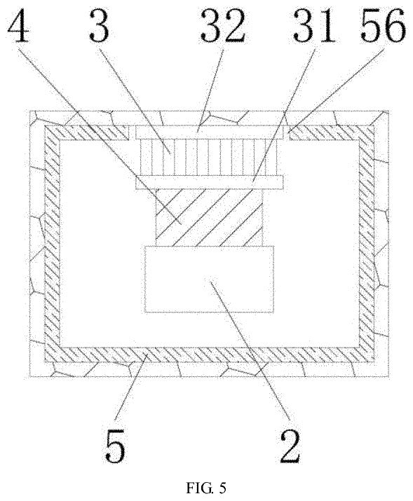

FIG. 5 is a schematic structural diagram of still another heat dissipation assembly provided by the present embodiment, which differs from the heat dissipation assembly described above in that the housing 1 is in a double-layered structure comprising an outer layer and an inner wall, and the heat insulation cavity 5 is constituted by a housing heat insulation layer that is attached to the inner wall of the housing 1. The outer layer of the housing 1 is configured to dissipate heat to the outside, and the housing heat insulation layer on the inner wall of the housing 1 prevents the heat on the housing 1 from entering the entire inner cavity of the housing 1. In addition to the heat generation device 2, other components may be disposed in the housing 1, and the heat of the housing 1 is prevented from being conducted to the other components by means of the housing heat insulation layer, thereby ensuring that the entire interior of the housing 1 will not be affected by the heat radiated from the housing 1, and ensuring that all the components in the housing 1 can operate at a relatively low constant temperature, so as to ensure that the components have stable operation performance and prolong the service life of the components.

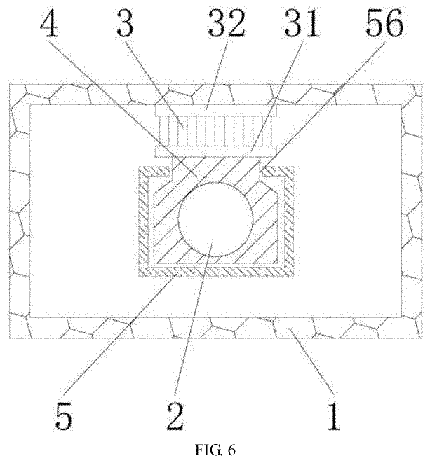

FIG. 6 is a schematic structural diagram of still another heat dissipation assembly provided by the present embodiment, which differs from the heat dissipation assembly described above in that the heat conductor 4 is attached to and cover the entire peripheral surface of the heat generation device 2, which can effectively increase the contact area, reduce the thermal resistance, improve the heat conduction efficiency, and improve the heat dissipation effect for the heat generation device 2.

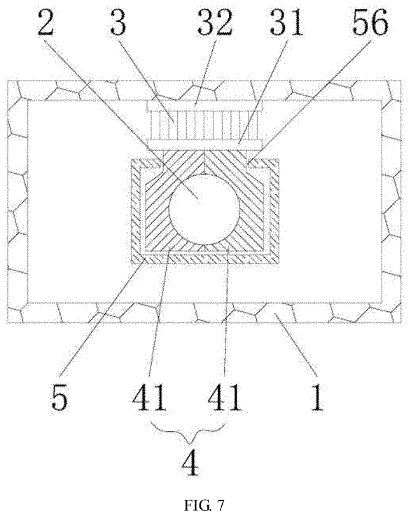

FIG. 7 is a schematic structural diagram of still another heat dissipation assembly provided by the present embodiment, which differs from the heat dissipation assembly described above in that the heat conductor 4 is constituted by detachably combining a plurality of split members 41 attached to the surface of the heat generation device 2, so that the heat conductor 4 can be assembled or disassembled more easily, and the structure of the split members is simpler, which is easy to manufacture and has a low cost.

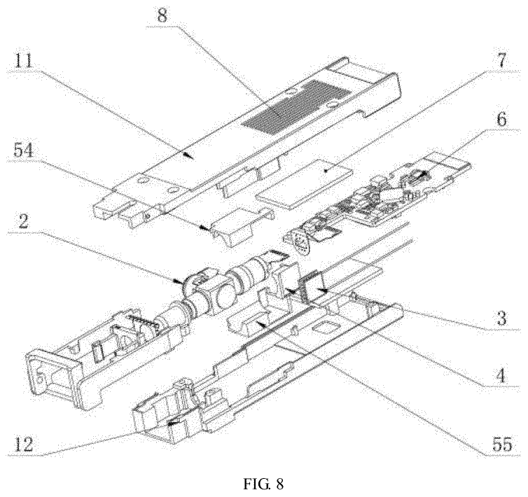

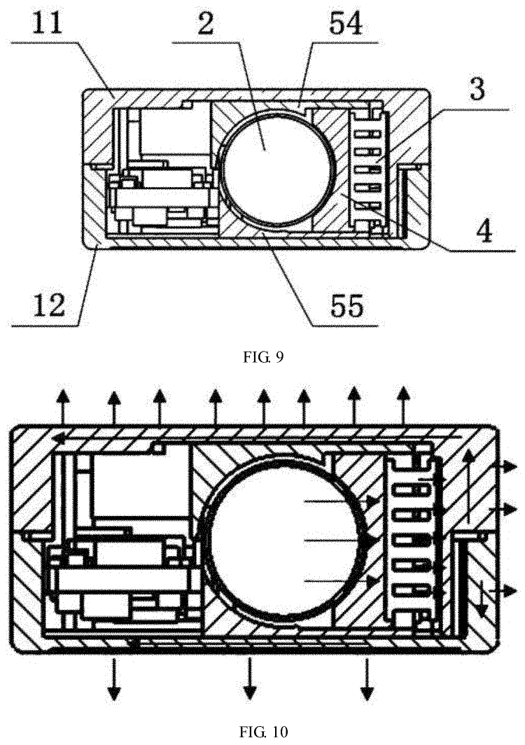

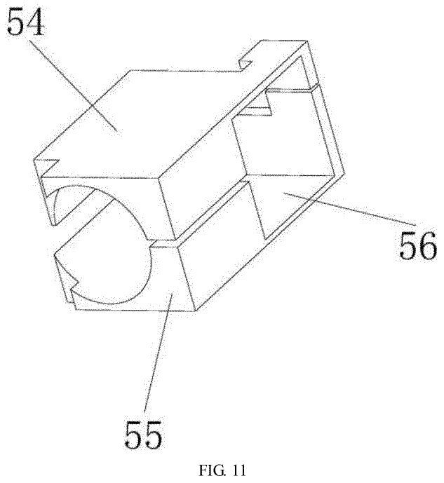

FIG. 8 to FIG. 11 show a communication module using the heat dissipation assembly provided in this embodiment. The communication module may be an optical device configured to receive and transmit an optical signal. The optical device may be a bi-directional optical sub-assembly (BOSA), a transmitting optical sub-assembly (TOSA), a receiving optical sub-assembly (ROSA), etc. The optical device may function as the heat generation device 2 in the present embodiment.

In the case where the heat generation device 2 is an optical device, the housing 1 may be a metal housing, the housing 1 is divided into an upper housing body 11 and a lower housing body 12, a circuit board 6 connected to the optical device serving as the heat generation device 2 is also provided in the housing 1, and the optical device is connected to the circuit board 6 by an electrical connector.

The heat generation portion of the optical device has a cylindrical structure, the side of the heat conductor 4 contacting the optical device and conducting heat has an arc shape matched with the surface of the heat generation portion of the optical device, thereby effectively increasing the contact area between the heat conductor 4 and the optical device.

Further, a heat conduction filler layer composed of silver colloid may be filled between the heat conductor 4 and the optical device, to further increase the contact area, improve the heat conduction efficiency, and improve the heat dissipation effect. Moreover, the heat conduction filler layer can also effectively connect and fix one side of the heat conductor 4 to the optical device, preventing the poor contact caused by transportation, vibration, etc. from affecting the heat dissipation effect. The other side of the heat conductor 4 is attached to the cold end 31 of the thermoelectric cooler 3. Moreover, a heat conduction filler layer composed of heat conductive adhesive is also filled between the heat conductor 4 and the cold end 31 of the thermoelectric cooler 3, to increase the contact area, improve the heat conduction efficiency, and ensure adequate heat dissipation.

Optionally, in this embodiment, the heat conductor 4 may be a metal heat conduction member, for example, a copper heat conduction member, which has good thermal conductivity, is simple to manufacture and has a low cost.

The hot end 32 of the thermoelectric cooler 3 may abut against the inner wall of the housing 1, and the heat conduction filler layer composed of heat conductive adhesive is also filled between the hot end 32 of the thermoelectric cooler 3 and the housing 1, so that the contact is more sufficient, the thermal resistance is reduced, and the heat conduction efficiency is improved to ensure that the heat generated by the optical device can be fully conducted to the housing 1 so as to realize heat dissipation. The housing 1 has a large surface area, and can radiate heat to the outside by radiation and convection, thereby improving the heat dissipation effect.

The distances from the optical device to the surfaces of the upper housing body 11 and the lower housing body 12 of the housing 1 are very small. Thus, the housing 1 will easily transfer heat back to the optical device by contact or radiation, resulting in poor heat dissipation, so that the temperature of the optical device fluctuates greatly, and the optical device cannot operate stably at a relatively low constant temperature, which thereby causes wavelength shift, and seriously affects communication reliability. In order to solve this problem, in the present embodiment, a heat insulation cavity 5 is provided on the periphery of the optical device, and the heat insulation cavity 5 is configured to wrap the heat generation portion of the optical device, thereby effectively preventing the high-temperature housing 1 from transferring heat back to the optical device.

Optionally, in the present embodiment, the heat insulation cavity 5 has a straight cylindrical structure as a whole, and is around the periphery of the cylindrical heat generation portion of the optical device, and the heat insulation cavity 5 is provided with a through hole 56 for allowing the heat conductor 4 to pass therethrough. The heat insulation cavity 5 may be formed by combining a heat insulation upper cavity 54 and a heat insulation lower cavity 55, and the through hole 56 may be provided at the combining surface between the heat insulation upper cavity 54 and the heat insulation lower cavity 55, which leads to a compact structure and convenient assembly and disassembly.

As shown in FIG. 10, the heat generated by the optical device is conducted to the heat conductor 4, the heat conductor 4 in turn transfers the heat to the thermoelectric cooler 3, and the thermoelectric cooler 3 in turn conducts the heat to the housing 1, so that the temperature of the housing 1 becomes high. Due to the large surface area of the housing 1, the high-temperature housing 1 will radiate heat to the outside, and due to the presence of the heat insulation cavity 5, the heat radiated from the housing 1 cannot be transferred back to the optical device, thereby ensuring an efficient and stable heat radiation effect of the optical device.

In this embodiment, there may be only the optical device in the heat insulation cavity 5, and the circuit board 6 is located at the outer side of the heat insulation cavity 5. In this case, the electrical connector configured to connect the optical device to the circuit board 6 passes through the heat insulation cavity 5. The heat insulation cavity 5 separates the optical device from the housing 1, the circuit board 6 and other components to prevent the heat on the housing 1 and the circuit board 6 from being conducted to the optical device, so as to ensure efficient heat dissipation and cooling effect of the optical device, ensure that the optical device can stably operate at a relatively low constant temperature, ensure stable operation performance, and improve communication reliability.

A heat conductive pad 7 may be disposed between the circuit board 6 and the housing 1. One surface of the heat conductive pad 7 is attached to the inner wall of the housing 1, and the other surface of the heat conductive pad 7 is attached to the heat generation element of the circuit board 6. In this way, the heat generated by the circuit board 6 is conducted to the housing 1, and is dissipated to the outside through the housing 1 in a manner of radiation and convection.

Further, in order to improve the outward heat dissipation effect of the housing 1, heat dissipation fins 8 may be provided on the outer wall of the housing 1 to increase the convection heat dissipation effect. In this way, it is possible to dissipate the heat on the housing 1 to the outside as soon as possible, thereby preventing the heat from accumulating on the housing 1 to affect the normal operation of the communication module.

Since the space for mounting the communication module is limited, a recess accommodating the heat dissipation fins 8 may be provided on the outer wall of the housing 1, so that the top surface of the heat dissipation fins 8 is not higher than the outer surface of the housing 1, thereby ensuring the compact structure of the communication module.

Optionally, the surface of the housing 1 may be coated with a high-emissivity radiation coating configured to accelerate heat diffusion of the housing 1, so as to avoid failure of the communication module caused by heat accumulation on the housing 1.

In this embodiment, the high-emissivity radiation coating may be a jumbo fullerene radiation heat dissipation powder layer. The jumbo fullerene radiation heat dissipation powder is a kind of functional energy-saving material with very high emissivity for heat radiation, which is used to enhance the radiation heat exchange between a heat source and a heated surface or between a heat source and a heated body, so as to achieve the object of improving the heat utilization rate and saving energy. In addition, the jumbo fullerene radiation heat dissipation powder has good thermal stability and chemical stability, and the coating material formed by mixing the jumbo fullerene radiation heat dissipation powder with ink, paint, etc. can high-strength bind with a metal or ceramic substrate, which after being prepared into a film material, can also dissipate heat in the manner of being attached to an object. Jumbo fullerene has a polyhedral carbon cluster with a closed multi-layer graphite structure. The central part of the graphite layer of the housing 1 is completely composed of six-membered rings, and the corners or the turning parts thereof are composed by five-membered rings. The multi-layer graphite structure of the housing 1 enables the housing 1 to have the advantages of good thermal conductivity, electric conductivity, good strength, chemical stability, etc., and achieve high radiant emissivity of 0.98 in the full-wave band, is suitable for binding with substrates with good heat conductivity, such as graphite sheets, copper foils, aluminum foils, etc., and can also be mixed with printing ink, spray paint, adhesive tape (film), adhesive, paste, foam, etc.

In summary, for the heat dissipation assembly and the communication module provide by the embodiments of the present disclosure, by providing a heat insulation cavity between the housing and the heat generation device, the case where the housing, after absorbing heat and getting a temperature rise, transfers heat back to the heat generation device can be avoided, which ensures the stable heat dissipation effect of the heat dissipation assembly, and thereby prevents temperature fluctuation of the heat generation device (for example, the communication module) using a heat sink, thus achieving stable operation performance and prolonging the service life of the heat generation device.

The above-described are only selected embodiments of the present disclosure. It should be noted that the selected embodiments should not be regarded as a limitation on the present disclosure, and the scope of protection of the present disclosure should be subject to the scope defined by the claims. For those of ordinary skills in the art, some improvements and modifications may also be made without departing from the spirit and scope of the present disclosure, and these improvements and modifications shall also be considered to be within the scope of protection of the present disclosure.

### INDUSTRIAL APPLICABILITY

The heat dissipation assembly and the communication module provided by the present disclosure can prevent the housing from transferring the absorbed heat back to the heat generation device, so that the heat dissipation assembly has a stable heat dissipation effect, which prevents temperature fluctuation of the heat generation device using the heat dissipation assembly, and can ensure the stability of the operation performance of the heat generation device.

1. A heat dissipation assembly, comprising a housing and a heat generation device disposed inside the housing, wherein the housing is provided therein with a heat insulation cavity around a periphery of the heat generation device, the heat insulation cavity is provided with a through hole, and the housing is provided therein with a heat conduction assembly passing through the through hole and configured to conduct heat of the heat generation device to the housing.

2. The heat dissipation assembly according to claim 1, wherein an inner wall of the heat insulation cavity is attached to a surface of the heat generation device.

3. The heat dissipation assembly according to claim 1, wherein only the heat generation device is provided in the heat insulation cavity, and the heat insulation cavity separates the heat generation device from the other parts disposed in the housing.

4. The heat dissipation assembly according to claim 1, wherein the heat insulation cavity is constituted by detachably combining a plurality of sub-cavities.

5. The heat dissipation assembly according to claim 4, wherein the heat insulation cavity comprises a heat insulation upper cavity and a heat insulation lower cavity matched with each other, and the through hole is provided at the combining surface between the heat insulation upper cavity and the heat insulation lower cavity.

6. The heat dissipation assembly according to claim 1, wherein the heat insulation cavity is of a double-layered structure, with an inner layer of the heat insulation cavity being a heat conduction cavity layer attached to a surface of the heat generation device, and an outer layer of the heat insulation cavity being a heat insulation cavity layer, and the heat conduction cavity layer is in thermal conduction with the heat conduction assembly and is configured to conduct heat to the housing by means of the heat conduction assembly.

7. The heat dissipation assembly according to claim 1, wherein the heat insulation cavity comprises a housing heat insulation layer that is attached to an inner wall of the housing.

8. The heat dissipation assembly according to claim 1, wherein the heat conduction assembly comprises a thermoelectric cooler, a cold end of the thermoelectric cooler is in thermal conduction with the heat generation device, and a hot end of the thermoelectric cooler is in thermal conduction with the housing.

9. The heat dissipation assembly according to claim 8, wherein the heat conduction assembly further comprises a heat conductor disposed between the thermoelectric cooler and the heat generation device, one side of the heat conductor is attached to the heat generation device, and the other side of the heat conductor is attached to the cold end of the thermoelectric cooler.

10. The heat dissipation assembly according to claim 9, wherein the side of the heat conductor attached to the heat generation device has a structural surface having the basically same shape as the surface of the heat generation device.

11. The heat dissipation assembly according to claim 9, wherein the heat conductor is attached to and cover the entire peripheral surface of the heat generation device.

12. The heat dissipation assembly according to claim 9, wherein the heat conductor is constituted by detachably combining a plurality of split members attached to the surface of the heat generation device.

13. The heat dissipation assembly according to claim 9, wherein the heat conductor is a metal heat conduction member.

14. The heat dissipation assembly according to claim 9, wherein a heat conduction filler layer made of a heat conduction interface material is filled between contact surfaces of the heat conductor and the heat generation device, between contact surfaces of the heat conductor and the thermoelectric cooler and between contact surfaces of the thermoelectric cooler and the housing.

15. The heat dissipation assembly according to claim 14, wherein the heat conduction filler layer between the heat conductor and the heat generation device is of an adhesive heat conduction interface material, and the heat conductor and the heat generation device are connected and fixed by the heat conduction filler layer.

16. The heat dissipation assembly according to claim 1, wherein the housing has a surface provided with a high-emissivity radiation coating.

17. The heat dissipation assembly according to claim 16, wherein the high-emissivity radiation coating is a jumbo fullerene radiation heat dissipation powder layer.

18. The heat dissipation assembly according to claim 1, wherein the housing has an outer wall provided thereon with heat dissipation fins.

19. The heat dissipation assembly according to claim 18, wherein one or more recesses are provided on the outer wall of the housing, the heat dissipation fins are accommodated in each of the one or more recesses, and a top surface of the heat dissipation fins is not higher than an outer surface of the housing.

20. A communication module provided with the heat dissipation assembly according to claim 1, comprising an optical device and a circuit board, the optical device serving as the heat generation device in the heat dissipation assembly according to claim 1, the circuit board being located inside the housing and at the outer side of the heat insulation cavity, and the device being connected to the circuit board by an electrical connector passing through the heat insulation cavity.
